(19) United States
(12) Patent Application Publication
(10) Pub. No.: US 2004/0151989 A1
(43) Pub. Date: Aug. 5, 2004

(54) Photo mask, method of manufacturing electronic device, and method of manufacturing photo mask

(75) Inventor: Kiyoshi Maeshima, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/620,367

(22) Filed: Jul. 17, 2003

(30) Foreign Application Priority Data
Jan. 31, 2003 (JP) 2003-024020(P)

(51) Int. Cl. G03F 9/00

(52) U.S. Cl. 430/5

(57) ABSTRACT

A photo mask includes a transmission region, a half-tone region, and a light-shielding region, and is formed in a one-time writing method. An outer periphery of each of a plurality of transmission regions is surrounded by the half-tone region. In a densest pattern region having a plurality of transmission regions arranged at a pitch of at most 0.32 μm which is smallest in the photo mask, the half-tone region surrounding an outer periphery of each of a pair of transmission regions is configured such that the light-shielding film is positioned between a pair of transmission regions adjacent to each other. Therefore, for a tri-tone mask, a photo mask, free from a forbidden region for all pitches, a method of manufacturing a electronic device, and a method of manufacturing a photo mask result.

### BACKGROUND OF THE INVENTION

1. Field of the Invention

The present invention relates to a photo mask, a method of manufacturing a electronic device, and a method of manufacturing a photo mask. More specifically, the present invention relates to a photo mask for use to form a fine pattern in a electronic device manufacturing step, a method of manufacturing electronic device, and a method of manufacturing a photo mask.

2. Description of the Background Art

A method of manufacturing a tri-tone mask having a transmission region, a half-tone region and a light-shielding region includes a one-time writing method. This one-time writing method is disclosed, for example, in Japanese Patent Laying-Open Nos. 8-328235 and 8-297357.

In the one-time writing method, a half-tone film and a light-shielding film are successively formed in a stacked manner on a transparent substrate and a resist is then applied thereon. A transmission region is written on the blanks coated with the resist, and the light-shielding film and the half-tone film are etched to form a transmission region where the surface of the transparent substrate is exposed. Thereafter, the resist is shrunken without being stripped off. The shrinking method includes ashing. In this state, using the resist as a mask, the light-shielding film is etched to form a half-tone region where the surface of the half-tone film is exposed. In other words, a region where the resist is shrunken serves as a half-tone region. A region where the light-shielding film is left serves as a light-shielding region. In this way, the tri-tone mask is formed in one-time writing.

Since the region where the resist is shrunken serves as a halt-tone region, a width of the half-tone region is approximately uniform (constant), though it depends on the distribution of the resist shrink.

In the tri-tone mask at a pitch equal to or larger than an intermediate pitch (where a pitch of patterns is larger than a pitch of dense patterns), a light-shielding film is necessary between patterns of the mask. This is because without a light-shielding film between patterns of the mask, a dimple occurs in a resist region where a pattern should not essentially be formed. On the other hand, in a dense pattern region (where a pitch of patterns is smaller than an intermediate pitch), a mask pattern can be formed at high resolution on a wafer even without arranging a light-shielding film between patterns of the mask. Therefore, a light-shielding film is not formed between fine patterns, as disclosed in Japanese Patent-Laying Open No. 2001-356467.

When the light-shielding film is not arranged between patterns in a dense pattern region, an ultrafine light-shielding film beyond mask manufacturing precision is created between the patterns in a pattern region having a pitch slightly larger than a pattern pitch in the dense pattern region, because the width of the half-tone region formed in one-time mask writing is constant.

It is noted that an ultrafine light-shielding region beyond mask manufacturing precision as used in the present specification refers to a light-shielding film of a design which is present or absent on a mask depending on manufacturing errors or variations in mask manufacturing processes.

Such an ultrafine light-shielding film beyond mask manufacturing precision affects the resolution of the mask when the pattern is transferred. The pattern pitch resulting from the ultrafine light-shielding film beyond mask manufacturing precision provides an unusable, forbidden region, thereby imposing strict limitations on the device design and fabrication.

### SUMMARY OF THE INVENTION

An object of the present invention is to provide a photo mask, free from a forbidden region for any pitch in a tri-tone mask, a method of manufacturing a electronic device, and a method of manufacturing a photo mask.

In accordance with the present invention, a photo mask, formed in a one-time writing method, includes a plurality of transmission regions each formed of an exposed portion of a transparent substrate, a half-tone region formed of an exposed portion of a half-tone phase shifting film provided on the transparent substrate, and a light-shielding region formed of a region where a light-shielding film on the half-tone phase shifting film is formed. An outer periphery of each of a plurality of transmission regions is surrounded by the half-tone region. In a densest pattern region having a plurality of transmission regions arranged at a pitch of at most 0.32 μm where the pitch of the transmission regions is smallest in the photo mask, the half-tone region surrounding an outer periphery of each of a pair of transmission regions is configured such that the light-shielding film is positioned between a pair of transmission regions adjacent to each other.

It is noted that in the photo mask that is formed by the one-time writing method, the width of the half-tone region is substantially equal (constant) for any pattern of any pitch.

In the photo mask in accordance with the present invention, in a densest pattern region in a dense pattern region (where a pitch of the transmission regions is 0.32 μm or less), where a pitch of the transmission regions is smallest in the photo mask, a light-shielding film is arranged between a pair of transmission regions adjacent to each other. Therefore, for all the pitches formed in a one-time mask writing method, a light-shielding film is arranged between a pair of transmission regions adjacent to each other. The line width of the light-shielding film in the densest pattern region is made greater than the ultra-fineness beyond mask manufacturing precision, so that a line width of a light-shielding film arranged between transmission regions is greater than the ultra-fineness beyond mask manufacturing precision for a pattern of any pitch, because a width of a half-tone region formed in the one-time mask writing method is constant. As a result, an ultrafine light-shielding film beyond mask manufacturing precision is not created and a forbidden region resulting from such a light-shielding region is thus eliminated, thereby reducing limitations on the device design and fabrication with a greater degree of freedom.

In accordance with the present invention, a method of manufacturing a photo mask includes the following steps.

First, a half-tone phase shifting film and a light-shielding film are successively formed on a surface of a transparent substrate. A photoresistive material is formed on the light-shielding film. The photoresistive material is patterned by photolithography to form an aperture exposing a partial surface of the light-shielding film, in the photoresistive material. The light-shielding film and the half-tone phase shifting film positioned immediately below the aperture are successively removed to expose the surface of the transparent substrate to form a plurality of transmission regions each formed of an exposed portion of the transparent substrate. The photoresistive material is shrunken, and an aperture size of the aperture is thus enlarged to expose a partial surface of the light-shielding film. The light-shielding film exposed from the enlarged aperture is removed to expose a partial surface of the half-tone phase shifting film, thereby forming a half-tone region formed of an exposed portion of the half-tone phase shifting film and forming a light-shielding region where the light-shielding film is left. The photoresistive material is removed. An outer periphery of each of a plurality of the transmission regions is formed to be surrounded by the half-tone region. In a densest pattern region having a plurality of the transmission regions arranged at a pitch of at most 0.32 μm where the pitch of the transmission regions is smallest in the photo mask, the half-tone region surrounding an outer periphery of each of a pair of the transmission regions is formed such that the light-shielding film is left between a pair of the transmission regions adjacent to each other.

In the method of manufacturing a photo mask in accordance with the present invention, as in the foregoing description, an ultrafine light-shielding film beyond mask manufacturing precision is not created and a forbidden region resulting from such a light-shielding film is thus eliminated, thereby reducing limitations on the device design and fabrication with a greater degree of freedom.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic planar view showing a configuration of a mask for manufacturing a semiconductor device in an embodiment of the present invention.

FIG. 2 is a schematic cross sectional view taken along line II-II in FIG. 1.

FIGS. 3-8 are schematic cross sectional views showing steps of a method of manufacturing a mask for manufacturing a semiconductor device in an embodiment of the present invention, in order.

FIG. 9 is a planar view showing a size of each part in a densest pattern region in the case of hole pattern.

FIG. 10 is a planar-view showing a size of each part in patterns arranged at a pitch equal to or greater than the densest pitch in the case of hole pattern.

FIG. 11 is a planar view showing a size of each part in a densest pattern region in the case of L/S pattern.

FIG. 12 is a planar view showing a size of each part in patterns arranged at a pitch equal to or greater than the densest pitch in the case of L/S pattern.

FIG. 13 is a conceptual view showing a method of manufacturing a semiconductor device using the mask for manufacturing a semiconductor device in an embodiment of the present invention.

FIGS. 14-16 are schematic cross sectional views of a semiconductor substrate showing steps of a method of manufacturing a semiconductor device, in order.

### DESCRIPTION OF THE PREFERRED EMBODIMENTS

In the following, an embodiment of the present invention will be described with reference to the figures.

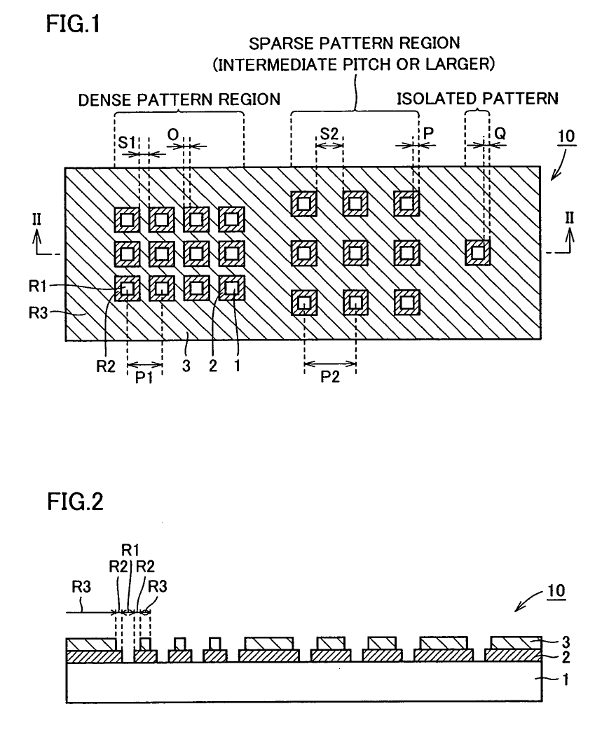

Referring to FIGS. 1 and 2, a mask 10 for manufacturing a semiconductor device in the present embodiment has a transparent substrate 1, a half-tone phase shifting film 2, and a light-shielding film 3.

Mask 10 for manufacturing a semiconductor device is a tri-tone mask including a plurality of transmission regions R1 each formed of an exposed portion of transparent substrate 1, a half-tone region R2 formed of an exposed portion of half-tone phase shifting film 2 provided on transparent substrate 1, and a light-shielding region R3 formed of a region in which a light-shielding film 3 is formed on half-tone phase shifting film 2. Half-tone phase shifting film 2 provides a phase difference of 180° in opposite with respect to transmission region R1 and has a light transmittance set high, for example, at 8% or higher.

Mask 10 for manufacturing a semiconductor device includes, for example, a dense pattern region, a sparse pattern region, and an isolated pattern, with different pitches of transmission region R1. As used herein a dense pattern region is a region where a pitch P1 of transmission region R1 is set such that a pitch of transmission region R1 projected on a wafer is 0.32 μm or less. A sparse pattern region is a region where a pitch P2 of transmission region R1 is set such that a pitch of transmission region R1 projected on a wafer exceeds 0.32 μm. An isolated pattern is a pattern isolated from the other transmission regions R1.

An outer peripheral region of each transmission region R1 in the dense pattern region, the sparse pattern region and the isolated pattern is surrounded by half-tone region R2. Furthermore, each outer peripheral region of the dense pattern region, the sparse pattern region, and the isolated pattern is surrounded by light-shielding region R3.

In the present embodiment, in the densest pattern region of the dense pattern region, where a pitch of transmission region R1 is smallest in mask 10 for manufacturing a semiconductor device, the width of half-tone region R2 surrounding the outer periphery of each of a pair of transmission regions R1 is set (designed) such that light-shielding film 3 is positioned between a pair of transmission regions R1 adjacent to each other. As a result, light-shielding film 3 is positioned between a pair of transmission regions R1 adjacent to each other in the dense pattern region and the sparse pattern region at any pitch, and line widths S1 and S2 of light-shielding film 3 each are greater than the ultra-fineness beyond mask manufacturing precision. In other words, the outer peripheral region of each transmission region R1 in the dense pattern region, the sparse pattern region and the isolated pattern is surrounded by half-tone region R2, and the outer peripheral region of half-tone region R2 is further surrounded by light-shielding region R3.

Mask 10 for manufacturing a semiconductor device is formed by a one-time writing method as described later. The widths O, P and Q of the respective half-tone regions R2 in the dense pattern region, the sparse pattern region and the isolated pattern are thus equal (constant).

It is noted that transmission region R1 in the present embodiment is, for example, an aperture for forming a hole pattern.

A method of manufacturing a mask for manufacturing a semiconductor device in the present embodiment will be described.

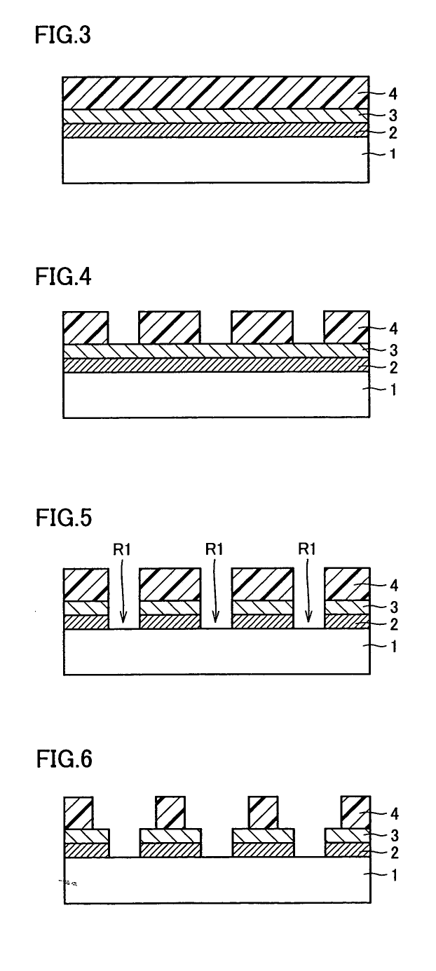

Referring to FIG. 3, half-tone phase shifting mask 2 and light-shielding film 3 are successively formed in a stacked manner on a surface of transparent substrate 1. Resist (photoresistive material) 4 is applied on light-shielding film 3.

Referring to FIG. 4, a transmission region is written on the blanks coated with resist 4, and resist 4 is then patterned.

Referring to FIG. 5, using the patterned resist 4 as a mask, light-shielding film 3 and half-tone phase shifting film 2 are successively etched. The surface of transparent substrate 1 is thus exposed to form transmission region R1.

Referring to FIG. 6, resist 4 is shrunken without being stripped off. The shrinking method includes, for example, ashing. Therefore, a partial surface of light-shielding film 3 is exposed.

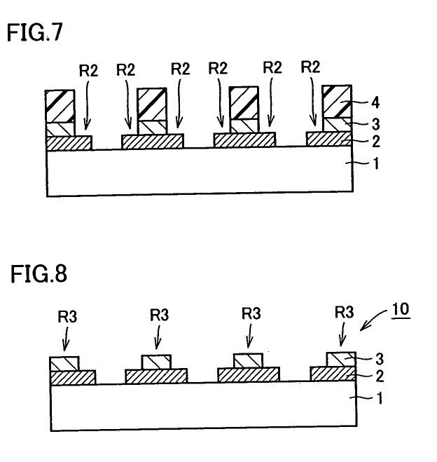

Referring to FIG. 7, in this state, the exposed light-shielding film 3 is etched away using resist 4 as a mask, so that the surface of half-tone phase shifting film 2 is exposed to form half-tone region R2. In other words, a region where resist 4 is shrunken serves as half-tone region R2. Resist 4 is thereafter stripped off.

Referring to FIG. 8, the surface of light-shielding film 3 is exposed by removing the resist as described above, and the region where light-shielding film 3 is left serves as light-shielding region R3. In this way, the mask for manufacturing a semiconductor device in the present embodiment is formed as a tri-tone mask in one-time writing.

It is noted that FIGS. 3-8 only show the densest pattern region for convenience of illustration.

The line width of the light-shielding region between transmission regions in the present embodiment will now be described.

In the present embodiment, the mask for manufacturing a semiconductor device is formed in one-time writing as described above. In this one-time writing, the widths O, P and Q of the respective half-tone regions R2 in the dense pattern region, the sparse pattern region and the isolated pattern region are approximately constant irrespective of pattern pitches P1, P2. In the present embodiment, even in the densest pattern region, light-shielding film 3 having a size S1 (line width) that can be designed and allows mask fabrication is arranged between transmission regions R1. If light-shielding film 3 is arranged between transmission regions R1 in the densest pattern region having the smallest pitch, it follows that light-shielding film 3 is present between transmission regions R1 in a pattern region of any pitch, because the widths O, P, Q of the half-tone region R2 are approximately constant irrespective of pattern pitches P1, P2, as described above. The size (line width) of light-shielding film 3 between transmission regions R1 is consequently equal to or greater than the size (line width) of the light-shielding film in the densest pattern region.

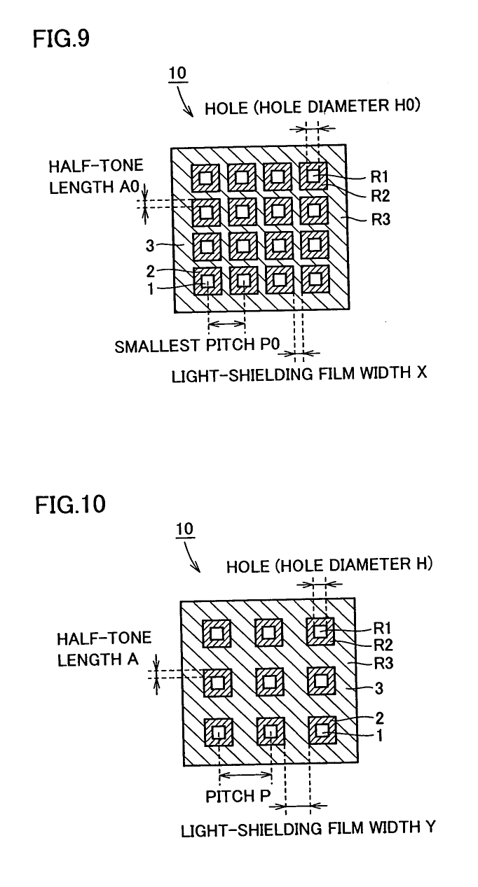

Referring to FIG. 9, in the densest pattern region in the case of hole pattern, A0 represents a half-tone length (a width of half-tone region R2), H0 represent a hole diameter (an aperture size of transmission region R1), P0 represents a pattern pitch, and X represents a transmission film width between patterns (a line width of light-shielding region R3). Light-shielding film width X is a width that can be processed accurately in mask fabrication.

Referring to FIG. 10, in the patterns arranged at a pitch equal to or larger than the densest pitch in the case of hole pattern, A represents a half-tone length, H represents a hold diameter, P represents a pitch, and Y represents a light-shielding film width.

Here, X=P0−(2A0+H0), and Y=P−(2A+H). Furthermore, A0≈A, as the half-tone length is approximately uniform.

Generally, when a dense pattern and a sparse pattern (or an isolated pattern) are finished in exposure transfer patterns of the same dimensions, the design on the mask should be such that a sparse pattern (or an isolated pattern) is sized larger than a dense pattern. Therefore, H>H0 where P >>P0, and X<Y holds as P−P0>H−H0. Furthermore, when P>P0, H≈H0, and X<Y also holds. As a result, the size (line width) of light-shielding film 3 between transmission regions R1 is naturally equal to or greater than the size (line width) of light-shielding film 3 in the densest pattern region. Therefore, the light-shielding film width in the densest pattern region is made greater than the ultra-fineness beyond mask manufacturing precision, so that the light-shielding film width can be greater than the ultra-fineness beyond mask manufacturing precision, for a pattern of any pitch, resulting in a light-shielding region that has no effect on mask precision for a pattern of any pitch.

As described above, in accordance with the mask for manufacturing a semiconductor device and a manufacturing method thereof of the present invention, in the densest pattern region where pitch P1 of the transmission region is smallest in the mask for manufacturing a semiconductor device, of the dense pattern region (the pattern region where pitch P1 of transmission region R1 is set such that a pitch of transmission region R1 projected on the wafer is 0.32 μm or less), light-shielding film 3 is arranged between a pair of transmission regions R1 adjacent to each other. Therefore, for all the pitches formed by the one-time mask writing method, light-shielding film 3 is arranged between a pair of transmission regions R1 adjacent to each other. Furthermore, line width S1 of light-shielding film 3 in the densest pattern region is made greater than the ultra-fineness beyond mask manufacturing precision, so that the line widths S1, S2 of light-shielding film 3 arranged between transmission regions R1 each are greater than the ultra-fineness beyond mask manufacturing precision, since the widths O, P and Q of half-tone region R2 formed by the one-time mask writing method are constant. As a result, an ultrafine light-shielding film beyond mask manufacturing precision is not created and the forbidden region resulting from such a light-shielding region is thus eliminated, thereby reducing limitations on the device design and fabrication with a greater degree of freedom.

Although the hole pattern has been described in the forgoing, the present invention is not limited thereto and may be applied to a line and space (L/S) pattern, similarly. In the following, the line width of the light-shielding region between transmission regions in the case of L/S pattern will be described.

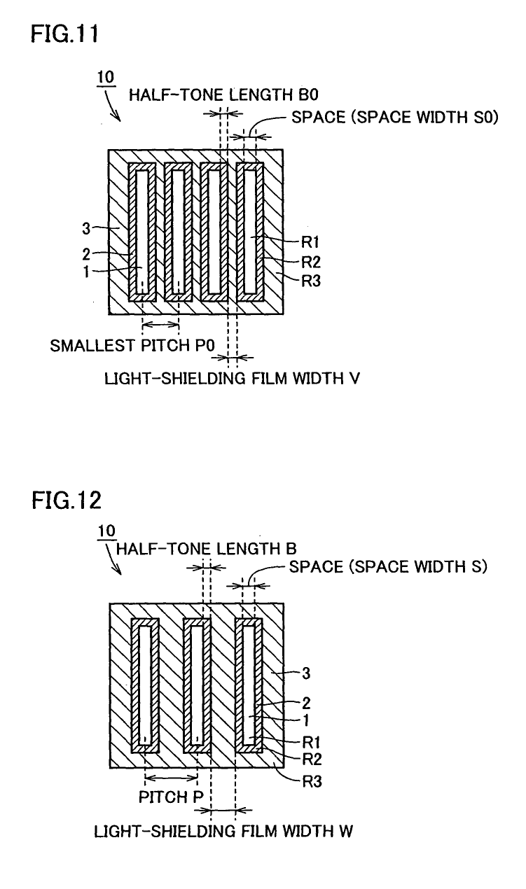

Referring to FIG. 11, in the densest pattern region in the case of L/S pattern, B0 represents a half-tone length, S0 represents a space width (an aperture width of transmission region R1), P0 represents a pattern pitch, and V represents a light-shielding film width between patterns. The light-shielding film width V is a width that can be processed accurately in mask fabrication.

Referring to FIG. 12, in the patterns arranged at a pitch larger than the densest pitch in the case of L/S pattern, B represents a half-tone length, S represents a space width, P represents a pitch, and W represents a light-shielding film width.

Here, V=P0−(2B0+S0), and W=P−(2B+S). Since this L/S pattern is formed in one-time writing as similar to the embodiment above, the half-tone length is approximately uniform, and B0≈B.

Generally, where a dense pattern and a sparse pattern (or an isolated pattern) are finished in exposure transfer patterns of the same dimensions, the design on the mask should be such that a sparse pattern (or an isolated pattern) is sized larger than a dense pattern, as in the foregoing description. Therefore, when P>>P0, S>S0 and V<W holds. Furthermore, when P>P0, S≈S0, and V<W also holds. Consequently, the size (line width) of light-shielding film 3 between transmission regions R1 is naturally equal to or greater than the size (line width) of light-shielding film 3 in the densest pattern region. Therefore, light-shielding film width in the densest pattern region is made greater than the ultra-fineness beyond mask manufacturing precision, so that the light-shielding film width can be made greater than the ultra-fineness beyond mask manufacturing precision for a pattern of any pitch, thereby resulting in a light-shielding region that has no effect on the mask precision for a pattern of any pitch.

A method of manufacturing a semiconductor device using the mask for manufacturing a semiconductor device in the present embodiment will now be described.

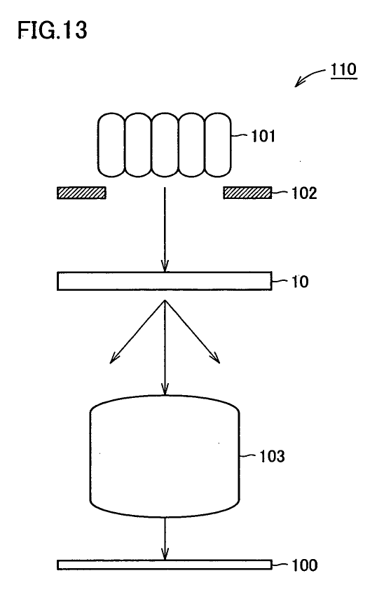

Referring to FIG. 13, a pattern of mask 10 for manufacturing a semiconductor device in the present embodiment is exposed on the resist applied on a surface of a semiconductor substrate 100 (for example, a semiconductor wafer), using a reduction projection exposure system 110.

Reduction projection exposure system 110 mainly includes a light source, a fly eye lens 101, a diaphragm 102, and a projection lens 103. The light emitted from the light source passes through fly eye lens 101 and diaphragm 102 to radiate onto mask 10 for manufacturing a semiconductor device. The light that radiates onto mask 10 for manufacturing a semiconductor device is reduced at a prescribed magnification by projection lens 103 to expose the resist on the surface of semiconductor substrate 100.

This reduction projection exposure system 110 has a magnification of ¼, for example, and uses excimer laser of KrF (248 nm wavelength) and ArF (193 nm wavelength), for example, for exposure.

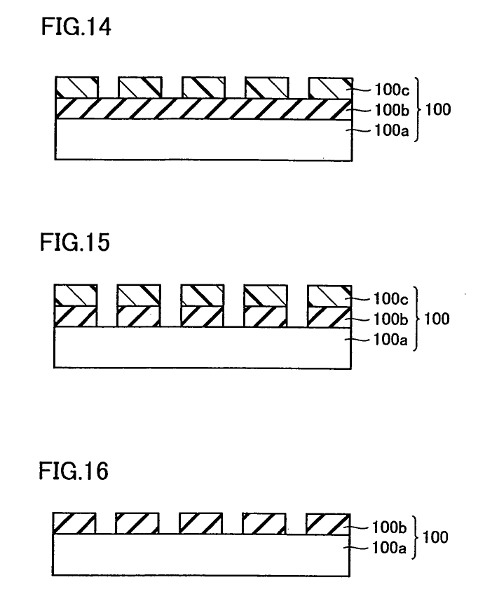

Referring to FIG. 14, after the exposure described above, resist 100c is patterned through development. This patterned resist 100c is used as a mask to etch the underlying film 100b.

Referring to FIG. 15, as a result of this etching, for example, hole patterns are formed in the etched film 100b and a partial surface of substrate 100a is exposed. Thereafter, resist 100c is removed, for example, by ashing.

Referring to FIG. 16, as a result of the removal of resist 100c as described above, the surface of the etched film 100b is exposed. A semiconductor device results in this manner. As a result, a semiconductor device having a pattern at high resolution can be manufactured.

It is noted that though a semiconductor device has been described as an electronic device in the foregoing, the present invention is also applicable to other electronic devices such as a thin film magnetic head, a liquid crystal display, or the like, other than a semiconductor device.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A photo mask, formed in a one-time writing method, comprising:
a plurality of transmission regions each formed of an exposed portion of a transparent substrate;
a half-tone region formed of an exposed portion of a half-tone phase shifting film provided on said transparent substrate; and
a light-shielding region formed of a region where a light-shielding film on said half-tone phase shifting film is formed, wherein an outer periphery of each of a plurality of said transmission regions is surrounded by said half-tone region, and
in a densest pattern region having a plurality of said transmission regions arranged at a pitch of at most 0.32 μm where the pitch of said transmission regions is smallest in said photo mask, said half-tone region surrounding an outer periphery of each of a pair of said transmission regions is configured such that said light-shielding film is positioned between a pair of said transmission regions adjacent to each other.

2. The photo mask according to claim 1 wherein said transmission region in said densest pattern region is an aperture for forming a hole pattern.

3. The photo mask according to claim 1 wherein said transmission region in said densest pattern region is an aperture for forming a line and space.

4. A method of manufacturing a electronic device using the photo mask of claim 1.

5. A method of manufacturing a photo mask, comprising the steps of:
successively forming a half-tone phase shifting film and a light-shielding film on a surface of a transparent substrate;
forming a photoresistive material on said light-shielding film;
patterning said photoresistive material by photolithography to form in said photoresistive material an aperture exposing a partial surface of said light-shielding film;
successively removing said light-shielding film and said half-tone phase shifting film positioned immediately below said aperture to expose the surface of said transparent substrate to form a plurality of transmission regions each formed of an exposed portion of said transparent substrate;
shrinking said photoresistive material to enlarge an aperture size of said aperture to expose a partial surface of said light-shielding film;
removing said light-shielding film exposed from enlarged said aperture to expose a partial surface of said half-tone phase shifting film, thereby forming a half-tone region formed of an exposed portion of said half-tone phase shifting film and forming a light-shielding region where said light-shielding film is left; and
removing said photoresistive material, wherein
an outer periphery of each of a plurality of said transmission regions is formed to be surrounded by said half-tone region, and
in a densest pattern region having a plurality of said transmission regions arranged at a pitch of at most 0.32 μm where the pitch of said transmission regions is smallest in said photo mask, said half-tone region surrounding an outer periphery of each of a pair of said transmission regions is formed such that said light-shielding film is left between a pair of said transmission regions adjacent to each other.
